(19) United States
(12) Patent Application Publication
(10) Pub. No.: US 2025/0023545 A1
(43) Pub. Date: Jan. 16, 2025

(54) SYSTEM FOR ENCAPSULATING A SURFACE ELASTIC WAVE DEVICE

(71) Applicant: Soitec, BERNIN (FR)

(72) Inventors: Thierry Laroche, Besançon (FR); Sylvain Ballandras, Besançon (FR); Gabrielle Aspar, Besançon (FR); Emilie Courjon, Franois (FR); Florent Bernard, Besançon (FR)

(21) Appl. No.: 18/706,565

(22) PCT Filed: Nov. 2, 2022
(86) PCT No.: PCT/EP2022/080596

§ 371 Date: May 1, 2024

(30) Foreign Application Priority Data
Nov. 2, 2021 (FR) FR2111634

(51) Int. Cl. H03H 9/10; H03H 3/08; H03H 9/145

(52) U.S. Cl. CPC H03H 9/1064; H03H 3/08; H03H 9/145

(57) ABSTRACT

A compact and robust encapsulation system for protecting a surface wave device comprises a SAW device and a sealing joint, which seals a second substrate to the base substrate of the SAW device so as to form a cavity, and an antenna connection means arranged outside the cavity on the encapsulation system.

### CROSS-REFERENCE TO RELATED APPLICATIONS

This application is a national phase entry under 35 U.S.C. § 371 of International Patent Application PCT/EP2022/080596, filed Nov. 2, 2022, designating the United States of America and published as International Patent Publication WO 2023/078959 A1 on May 11, 2023, which claims the benefit under Article 8 of the Patent Cooperation Treaty of French Patent Application Serial No. FR2111634, filed Nov. 2, 2021.

### TECHNICAL FIELD

The present disclosure relates to elastic surface wave devices, also known as surface acoustic wave devices or SAW devices. It relates, in particular, to a system for protecting the SAW devices, as well as to a corresponding method for manufacturing such a device.

### BACKGROUND

SAW devices are sensitive to the fluctuations in the resonance frequency of elastic waves on the surface of piezoelectric materials in response to external stimuli. These external stimuli can be of electrical, physical, chemical or biological nature. The versatility, reliability, sensitivity and economical production of these devices make their application highly desirable in a wide range of fields. SAW devices are used in a wide range of applications, including as temperature sensors, pressure sensors, force sensors, etc.

The usage of SAW devices presents two main limitations: on the one hand, the risks to correct operation due to exposure of the sensitive parts of the devices to environmental externalities, and on the other hand, the bulkiness of communication devices for connectivity with remote controllers. It is disclosed in S. Ballandras et al, “P1I-5 Micro-Machined, All Quartz Package, Passive Wireless SAW Pressure and Temperature Sensor,” 2006 IEEE Ultrasonics Symposium, 2006, pp. 1441-1444, doi: 10.1109/ULTSYM.2006.363, in particular, on p. 1443, a first encapsulation system for protecting a sensor comprising three SAW devices for determining pressure and temperature.

In view of the above, the aim of the present disclosure is to provide an improved SAW device protection solution, in particular, that combines robustness with compactness and a more economical production.

### BRIEF SUMMARY

In this respect the present disclosure relates to an encapsulation system for a surface acoustic wave (SAW) device, comprising: the SAW device comprising at least one base substrate and an interdigital transducer, also called comb transducer or interdigitated transducer, formed on the base substrate; a sealing joint, which seals a second substrate with the base substrate so as to form a cavity enveloping the interdigital transducer; and an antenna connection means, connected to at least one interdigital transducer. The encapsulation system is characterized in that the antenna connection means, in particular, a miniature coaxial radio frequency connector, is arranged outside the cavity on the base substrate or on the second substrate.

By integrating the antenna connection means directly into the encapsulation system, a more robust, compact and cost-effective SAW device protection than previously known can be achieved. In this way, direct integration of the antenna can eliminate the communication paths previously needed and the additional constraints presented by these previously known configurations. This has a number of advantages:

Firstly, the total space occupied by the system can be reduced, increasing its compactness and versatility of placement, particularly in existing structures and confined spaces.

Secondly, the number of components and production steps in the system can be reduced, lowering the production costs of such an encapsulation system.

Finally, by reducing the lengths of the conductive communication paths between the SAW device and a connection means for a remote antenna, the exposure of the communication paths to the risks presented by the environment can be advantageously dissipated by this encapsulation system. The reliability and robustness of the protected surface elastic wave device can thus be increased.

In one embodiment of the present disclosure, the connection between the interdigital transducer and the antenna connection means may comprise a wire bonding.

Establishing a connection comprising a wire bonding, for example, comprising a plurality of bond wires, can ensure communication between the interdigital transducer(s) with inexpensive means. For example, commercially available wires with conductive elements made of materials such as aluminum, copper, silver, platinum or gold can be used. As the physical, electrical and electromagnetic properties of these wires have been studied and predetermined, the communication between interdigital transducers and connection means can be dimensioned and operated with high precision.

In one embodiment of the present disclosure, the connection between the interdigital transducer and the antenna connection means may comprise at least one via traversing the second substrate.

The formation of one or more vias forming electrically conductive metal bridges in the second substrate can make it possible to establish a communication link between the interdigital transducer(s) inside the cavity of the encapsulation system, and an antenna connection means arranged on the second substrate. In this way, the communication link travels mainly inside the cavity of the encapsulation system, which can advantageously protect the communication from risks presented by the environment, such as high temperatures, chemical pollution or mechanical shocks. For example, the via can be assembled in the second substrate with an electrical routing, such as an electrically conductive track or path, arranged on the second substrate so as to establish an electrical connection with an antenna connection means. Within the cavity, electrical connection of the vias to the SAW device may be made, for example, using one or more solder bumps placed in the cavity between the SAW device and the second substrate, establishing an electrical connection with the vias in the second substrate.

In one example, the sealing joint is formed using glass frit, and the solder bumps are made of a noble metal, in particular, gold.

In one embodiment of the present disclosure, the connection between the interdigital transducer and the antenna connection means may comprise at least one metal pad formed on or in the base substrate and traversing the sealing joint.

The formation of such a metal pad across the sealing joint can enable reconnecting and communicating with one or more interdigital transducers hermetically sealed within the cavity of the encapsulation system following the sealing of the two substrates, without degrading or modifying the substrates themselves. Furthermore, by virtue of such a conductive connection pad traversing the sealing joint, the connection with an antenna connection means arranged outside the cavity on a base substrate or a second substrate can be operated and adjusted after the hermetic cavity has been closed, without constraints related to the restricted space of the cavity or to the sequencing of the production stages of the encapsulation system. The metal pad may be a metallic track in the same material as the interdigital transducer(s), for example, aluminum, gold, platinum or copper or a mixture of these materials, in particular, AlCu.

In one embodiment of the present disclosure, the face of the base substrate opposite the second substrate may comprise a metallic layer.

The purpose of metallizing the rear surface of the base substrate of the encapsulated SAW device in this way is to obtain improved thermal conductivity, in particular, to optimize the correct operation of a SAW device arranged as a temperature sensor.

In one embodiment of the present disclosure, the base substrate may be provided with at least one metal via, in particular, a via arranged so as to be electrically insulated from the interdigital transducer and preferably of the same material as a metallic layer on the side of the base substrate opposite the second substrate. In another mode, the at least one metal via passes completely through the base substrate from the lower face to the upper face of the base substrate and/or passes only partially through the base substrate, starting from the lower face but not ending in the upper face, in particular, in the part of the base substrate facing the electrodes. Thus, without disturbing the waves propagating close to the upper surface of the base substrate, a thermal bridge can be created.

In this alternative embodiment, the one or more metal vias added to the base substrate can act as a thermal bridge for the SAW device and similarly enable the correct operation of a SAW device configured as a temperature sensor to be optimized. The metal vias can preferably be made of the same material as a thermally conductive metallic layer arranged on the base substrate. This further increases heat conduction to the SAW device. In addition, the vias added to the base substrate can be arranged so as to be electrically insulated from the interdigital transducer(s). This reduces the risk of short-circuiting the electrodes of the transducer(s) of the SAW device.

In one embodiment of the present disclosure, the sealing joint can be formed by anodic welding or glass frit.

By forming the sealing joint by anodic welding, a highly durable and hermetic seal between the two substrates can be achieved. Welding is particularly advantageous because it does not require the use of additional sealing materials, which can be costly and interfere with the proper operation of the SAW device.

The use of glass frit to seal the substrates and form the hermetic cavity can provide a durable and hermetic seal, which is also compatible with the introduction of conductive metal pads across the sealing joint, without damaging either the sealing joint or the pad(s) themselves. In this way, reconnecting with the SAW device enclosed in the encapsulation system cavity is facilitated.

In this embodiment, the glass frit can also be chosen to have a thermal expansion coefficient corresponding to that of the material of the base substrate and/or the second substrate.

By choosing a glass frit material whose thermal expansion coefficient matches that of the base substrate material or of the second substrate material, preferably both, thermoelastic stresses induced by temperature variations can be limited, and even greatly reduced. Such a choice of material can therefore increase the mechanical durability of the encapsulation system and the operational reliability of a SAW device.

In one embodiment of the present disclosure, the base substrate may comprise a piezoelectric material, in particular, a material selected from quartz (SiO₂), lithium tantalate (LiTaO₃), lithium niobate (LiNbO₃), aluminum nitride (AlN), zinc oxide (ZnO), gallium orthophosphate (GePO₄), barium titanate (BaTiO₃), langasite (La₃Ga₅SiO₁₄), langanite (La₃Ga₅·5NbO·5O₁₄), gallium nitride (GaN), lead titano-zirconate (PZT) or langatate (La₃Ga₅·5TaO·5O₁₄).

These materials have resonant frequencies that are particularly sensitive to external stimuli and can therefore be advantageously used in SAW devices.

In one embodiment of the present disclosure, the second substrate may comprise a same material as the base substrate.

By assimilating the material of the second substrate to that of the base substrate, the thermal expansion differential between the two substrates can be reduced, thereby advantageously increasing the durability and robustness of the seal, and therefore the hermeticity of the encapsulation system.

The present disclosure also relates to a method for manufacturing an encapsulation system for a SAW device, in particular, an encapsulation system as described above. The method is characterized in that it comprises the following steps:
i. providing a base substrate comprising at least one interdigital transducer,
ii. sealing a second substrate to the first substrate so as to form a cavity enveloping the interdigital transducer(s), and
iii. arranging an antenna connection means, in particular, a miniature coaxial radio frequency connector, outside the cavity on the base substrate or the second substrate.

As indicated above, this method can result in a SAW device encapsulation system that provides more robust, compact and cost-effective protection of the sensitive parts of such a device than previously known.

According to an advantageous feature, the second substrate of step ii) may be provided with at least one via and the method may further comprise a step of electrically connecting the at least one interdigital transducer with the antenna connection means using the at least one via. Such a via through the second substrate may enable the electrical connection to be established between the interdigital transducer of step i enveloped in the cavity, and the antenna connection means arranged according to step iii on the second substrate. In this way, an electrical connection can be obtained, which travels mainly, or at least partly, inside the cavity formed by the seal, which can advantageously protect this connection from environmental risks. For example, the via can be assembled in the second substrate with electrical routing arranged on the second substrate and with solder bumps arranged in the cavity contacting the interdigital transducer.

According to another advantageous feature, the base substrate provided in step i may comprise a metallic layer on its side opposite the second substrate and/or at least one metal via. This feature or these features may allow a better thermal conductivity to the encapsulated SAW device and thereby an improved use of the SAW device, for example, as a temperature sensor. In particular, the vias included in the base substrate can be arranged so as to be electrically insulated from the interdigital transducer(s). This advantageously reduces the risk of short-circuiting the electrodes of the interdigital transducer(s).

In a further advantageous feature of the method, step ii may comprise forming at least one metal pad traversing the sealing joint. The formation of such a metal pad is advantageous because it can facilitate the establishment of a communication link with one or more interdigital transducers hermetically sealed in the cavity of the encapsulation system without modifying or damaging one of the two substrates, after the two substrates have been sealed.

As a further advantageous feature of the method, step iii may comprise a wired connection. Wired cabling can provide an inexpensive and reliable communication link.

### BRIEF DESCRIPTION OF THE DRAWINGS

The objects, features and advantages of the present disclosure as set out above will be more fully understood and appreciated by studying the following more detailed description of preferred embodiments of the present disclosure, together with the appended drawings.

FIG. 1 schematically represents a cross-sectional view of an encapsulation system according to a first embodiment of the present disclosure, in which the antenna connection means is arranged on the base substrate.

FIG. 2 schematically represents a cross-sectional view of an encapsulation system according to a second embodiment of the present disclosure, in which the antenna connection means is arranged on the second substrate.

FIG. 3 schematically represents a cross-sectional view of an encapsulation system according to a third embodiment of the present disclosure, in which the antenna connection means is also arranged on the second substrate.

FIG. 4 schematically represents a cross-sectional view of an encapsulation system according to a fourth embodiment of the present disclosure.

FIG. 5 schematically illustrates an example of a method according to the present disclosure.

### DETAILED DESCRIPTION

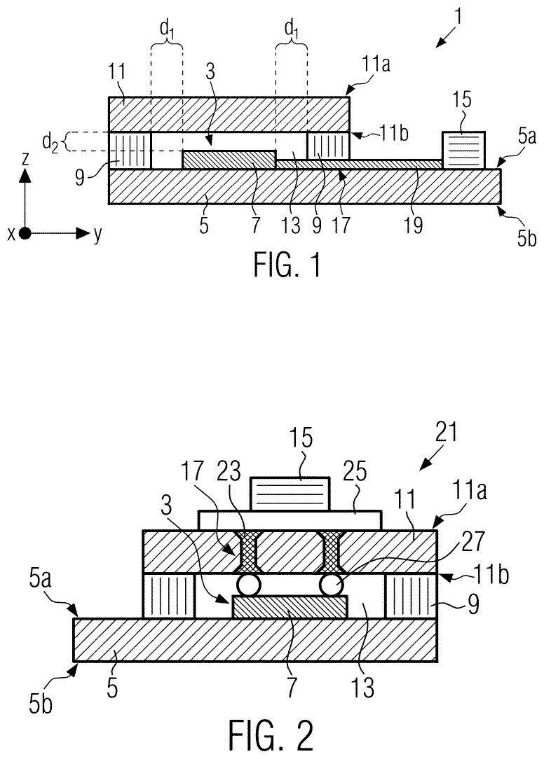

In what follows, the same references in the figures are used for elements of the same nature. The figures are schematic representations, which, for the sake of legibility, are not to scale. In particular, the thicknesses in the Z direction of the individual elements in FIGS. 1 to 4 are not to scale either in relation to each other or in relation to the dimensions of the elements in the Y direction.

FIG. 1 schematically represents a cross-sectional view of a first embodiment of the encapsulation system object of the present disclosure. It shows an encapsulation system 1 of a SAW device 3 comprising a base substrate 5 and at least one interdigital transducer 7, or “IdT” for the acronym of the English term “Interdigital Transducer,” having two metal electrodes with interdigital combs. The SAW device 3 may include other elements, such as at least one mirror, at least one resonance cavity, electrical connections, electronic components, etc. FIG. 1 also shows a sealing joint 9 sealing a second substrate 11 to the base substrate 5 to form a cavity 13.

The base substrate 5 and the second substrate 11 are arranged substantially in the xy plane in the Cartesian reference system shown in FIG. 1. Thus, the base substrate 5 has, relative to the z axis, an upper face 5a and a lower face 5b. Similarly, the second substrate 11 has an upper face 11a and a lower face 11b. Also shown schematically is a radio frequency connector 15, in particular, a miniature coaxial radio frequency connector, arranged outside the cavity 13 on the base substrate 5. The SAW device 3 is electrically connected to the radio frequency connector 15 using an electrical connection 17, for example, a conductive metal pad 19 arranged on the upper face 5a of the base substrate 5. The electrical connection 17 extends from inside the cavity 13 through the sealing joint 9 to the radio frequency connector 15.

The base substrate 5 is a piezoelectric substrate, for example, a bulk or piezo-on-insulator (POI) substrate. For example, the base substrate 5 is a single-crystal SiO₂ quartz substrate, in particular, with an ST crystal orientation cut.

Other piezoelectric materials are possible for the base substrate 5, such as lithium tantalate (LiTaO₃), lithium niobate (LiNbO₃), aluminum nitride (AlN), zinc oxide (ZnO), gallium orthophosphate (GaPO₄) aluminum nitride (AlN), zinc oxide (ZnO), gallium orthophosphate (GaPO₄), barium titanate (BaTiO₃), langasite (La₃Ga₅SiO₁₄), langanite (La₃Ga₅·5NbO·5O₁₄), gallium nitride (GaN), lead titano-zirconate (PZT) or langatate (La₃Ga₅·5TaO·5O₁₄).

The second substrate 11 is preferably made of the same material as the base substrate 5. By choosing the same material for the second substrate 11, the thermal expansion differential between the two substrates is reduced. This means that the device can be used over a wide temperature range, for example, from 75 K to 700 K, without being exposed to mechanical stress induced by temperature changes. In this way, the durability of the encapsulation system 1 can be improved.

The second substrate 11 is sealed to the base substrate 5 using the sealing joint 9. In the case of a base substrate 5 and a second substrate 11 made of quartz, a glass frit seal is preferably used to form the sealing joint 9 surrounding the transducer 7 disposed on the upper face 5a of the base substrate 5.

Because of the material match, glass frit sealing is particularly recommended in this case where quartz is chosen as the material for both the base substrate and the second substrate, as the thermal expansion coefficient is essentially the same.

Depending on the choice of substrate material, another method of sealing the substrates may be used, for example, anodic welding, adhesive bonding or eutectic bonding.

Preferably, the sealing joint 9 is arranged in such a way as to leave a space d1 around the transducer 7 and any other element of the SAW device 3, so as not to interfere with its operation. Typically, the width of the space d1 is at least 450 μm, preferably at least 500 μm.

A further gap d2, having a height typically of at least 5 μm, in particular, between 6 μm and 9 μm, is provided between the lower face 11b of the second substrate 11 and the upper edge in the Z direction of the transducer 7 or any other element of the SAW device 3.

The contour defined by the sealing joint 9 on the upper face 5a of the base substrate 5 may be substantially circular, rectangular or customized depending on the arrangement of the SAW device 3 and its components, or depending on the surface of the base substrate 5 requiring encapsulation protection.

The assembly of the base substrate 5 with the sealing joint 9 and the second substrate 11 creates the cavity 13 inside the assembly in which the sensitive parts of the SAW device 3 are located, thus establishing an encapsulation of the sensitive parts, and, in particular, of the transducer 7. In some embodiments, the cavity 13 in which the transducer 7 is located may be vacuum-sealed or under a controlled atmosphere, such as a nitrogen atmosphere.

In this embodiment, the antenna connection means chosen is the radio frequency connector 15. Preferably, the radio frequency connector 15 is a Hirose U.FL type male connector, chosen as the antenna connection means used for remote communication with the SAW device 3.

This connector is particularly advantageous because of its small dimensions, with a diameter of around 1.25 mm and a mating height of less than 2 mm, and its conduction properties, with a bandwidth of up to 18 Ghz.

The connector is also robust enough to withstand at least 10,000 mating cycles.

Other miniature or micro-miniature coaxial connectors than the Hirose U.FL type are also conceivable, and, in particular, connectors according to IEC 61169-1 such as MCX, MMCX, SSMA, SSMB connectors, and, in particular, radio frequency connectors according to IEC 61169-65 or according to IEC 61169-64.

The electrical connection 17, made by the metal pad 19, establishes a communication link with the transducer 7 and enables radio frequency signals to be transmitted for remote communication with the SAW device 3.

The method described above and illustrated in FIG. 1 provides an encapsulation system 1 for a SAW device 3 comprising at least one interdigital transducer 7 formed on a base substrate 5, protecting the sensitive parts of the SAW device 3 against the risks presented by the environment, in particular, chemical pollution, mechanical shocks and/or excessively high temperatures or pressures.

By integrating a radio frequency connector 15 for communication with the SAW device 3 directly into the encapsulation system of the SAW device, a versatile, economical and reliable SAW device 3 protection solution is obtained.

This method is particularly advantageous as it avoids the need to modify or damage the second substrate 11 to establish the connection between the antenna connection means and the interdigital transducer 7. As an additional advantage, this method for manufacturing makes it possible to obtain a thin encapsulated device in the Z direction.

According to a second embodiment of the present disclosure illustrated in FIG. 2, the radio frequency connector 15 is arranged on the second substrate 11. This embodiment differs from the embodiment described above in relation to FIG. 1, in particular, by this different arrangement of the radio frequency connector 15, as well as by the separate implementation of the electrical connection 17 between the radio frequency connector 15 and the interdigital transducer 7.

The encapsulation system 21 according to the second embodiment shown in FIG. 2 comprises, like the first embodiment shown in FIG. 1, the SAW device 3 with the base substrate 5 and the interdigital transducer 7 and the sealing joint 9 sealing the second substrate 11 to the base substrate 5 so as to form the cavity 13. FIG. 2 also schematically illustrates the radio frequency connector 15 arranged outside the cavity 13 on the upper face 11a of the second substrate 11 and connected by the electrical connection 17 with the interdigital transducer 7.

In this embodiment illustrated in FIG. 2, at least one via 23, in this case two vias, passes through the second substrate 11 to allow an electrical connection between the radio frequency connector 15 and the SAW device 3, in particular, the transducer 7. In this embodiment, the electrical connection is made by way of an electrical routing 25 arranged on or in the upper face 11a of the second substrate 11, but, alternatively, the radio frequency connector may be in direct contact with the vias 23. Inside the cavity 13, the electrical connection of the vias 23 with the SAW device 3 is made using one or more solder beads or solder bumps 27, placed in the cavity 13 between the SAW device 3, in particular, its transducer 7, and the lower face 11b of the second substrate 11 establishing an electrical connection with vias 23 in the second substrate 11.

In one example, the sealing joint 9 is formed using glass frit, and the solder bumps 27 are made of a noble metal, in particular, gold.

By implementing this second method, a versatile, economical and reliable SAW device protection solution is also obtained. In particular, this method is advantageous because it avoids interrupting and damaging the sealing joint 9, and makes it possible to obtain a device that is thinner in the Y direction. This method has the additional advantage of being particularly fast to manufacture, with just one sealing stage. No assembly of parts or connections is necessary after the base substrate 5 has been sealed to the second substrate 11.

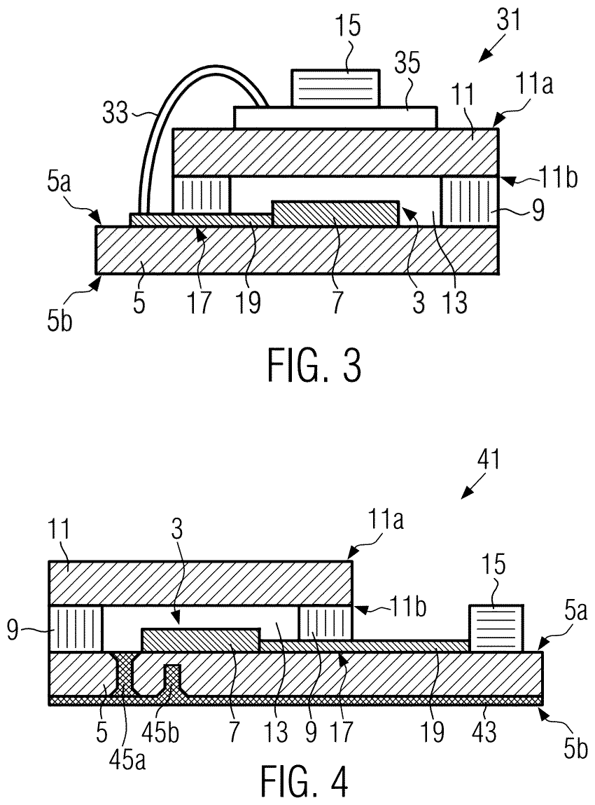

According to a third embodiment of the present disclosure illustrated in FIG. 3, a radio frequency connector 15 is arranged on the second substrate 11 and interfaced with the transducer 7 by an electrical connection 17 comprising a wire bonding 33, that is, one or more bond wires.

The third embodiment shown in FIG. 3 comprises another encapsulation system 31. In the third embodiment, the radio frequency connector 15 is positioned on the upper face 11a of the second substrate 11, but the electrical connection with the SAW device 3 is no longer made using vias 23 as illustrated in the second embodiment of the present disclosure.

In this third embodiment, the electrical connection 17 comprises the conductive metal pad 19 passing through the sealing joint 9 as in the first embodiment and additionally a wire bonding 33. The wire bonding 33 establishes the electrical connection between the conductive metal pad 19 interfacing with the interdigital transducer 7 of the SAW device 3 and the antenna connection means. This connection may be direct or by way of a conductive track 35 arranged on the upper face 11a of the second substrate 11, on which the connection means for the antenna is arranged, in particular, a radio frequency connector 15.

This third embodiment therefore also provides a versatile, economical and reliable SAW device protection solution.

The fourth embodiment shown in FIG. 4 is based on the first embodiment and comprises an encapsulation system 41 with a metallic layer 43 on the lower face 5b of the base substrate 5. In addition, at least one, here two, metal vias 45a, 45b are formed in the base substrate 5. One metallic via 45a passes completely through the base substrate from the lower face 5b to the upper face 5a. Another via 45b only passes partially through the base substrate 5, starting from the lower face 5b but not ending in the upper face 5a. The via 45b therefore does not modify the composition of the upper face 5a of the base substrate 5.

The metallic layer 43 and metal vias 45a, 45b improve thermal conductivity between the ambient environment of the encapsulated SAW device 3 and the interior of the cavity 13 in which the interdigital transducer 7 is located. The metal vias 45a, 45b form thermal bridges in the base substrate 5. They then represent point locations of increased thermal conductivity in the base substrate 5 of the SAW device 3, which can direct thermal energy from the cavity 13 to the surrounding environment. This improves the use of the encapsulation system object of the present disclosure, in particular, when the SAW device 3 is arranged as a temperature sensor.

The metal vias 45a, 45b are arranged in such a way that they are electrically insulated from the interdigital transducer(s) 7. In this way, the correct operation of the SAW device 3 can be guaranteed. In particular, the risk of short-circuiting the electrodes of an interdigital transducer is reduced.

For example, as illustrated in FIG. 4, one or more non-traversing metal vias 45b may be arranged opposite the interdigital transducer 7. Alternatively or additionally, in areas of the SAW device 3, which do not interfere with the operation of the interdigital transducer 7, through metal vias 45a may be arranged in the base substrate 5. In this way, thermal conductivity is increased without interfering with the correct operation of the SAW device 3 and, in particular, the interdigital transducer 7, which is sensitive to variations in the frequency of elastic surface waves on the upper face 5a. In other embodiments, the use of traversing metal vias 45a or non-traversing metal vias 45b may be omitted or mixed depending on the structure and dimensions of the encapsulation system 1, 21, 31, 41.

Furthermore, in order to optimize temperature homogenization of the SAW device, several metal vias 45a, 45b can be arranged in a matrix shape for better thermal distribution, and this in a way that does not hinder the creation and propagation of the elastic wave.

The metal vias 45a, 45b and the metallic layer 43 on the lower face 5b of the base substrate 5 are preferably made of the same metal material. This enables them to be produced together in one production stage and facilitates the migration of heat flows.

In this way, this fourth embodiment also presents a versatile, economical and reliable SAW device protection solution, which, moreover, is optimized for a SAW device arranged as a temperature sensor. Alternatively, this fourth embodiment can also be based on the second or third embodiment.

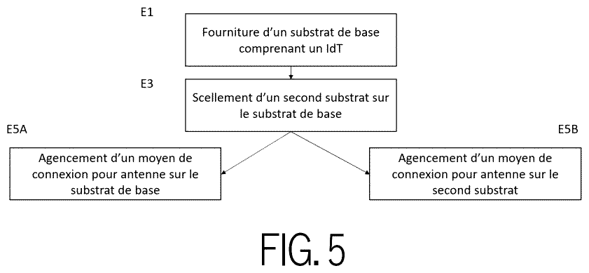

A method for manufacturing a SAW device encapsulation system is described with reference to FIG. 5, according to a fifth embodiment of the present disclosure. This method can be implemented, for example, in order to obtain an encapsulation system as illustrated in FIGS. 1 to 4. FIG. 5 shows a number of steps to be carried out in sequence.

The method begins with a step E1 of providing a base substrate 5 comprising at least the interdigital transducer 7. For example, an ST-cut quartz base substrate 5 is provided.

In a step E3, a second substrate 11 is sealed to the base substrate 5 to form a cavity 13 enveloping the transducer(s) 7. The second substrate 11 can be sealed to the base substrate 5 using glass frit thereby forming a sealing joint 9 to obtain the cavity 13.

During step E5A, an antenna connection means, such as a radio frequency connector 15, is arranged outside the cavity 13 on the base substrate 5. Alternatively, in step E5B, the antenna connection means is arranged on the second substrate E5B or on the electrical routing 25, 35 outside the cavity 13. The radio frequency connector 15 is, for example, welded onto the electrical routing 25, 35 or the metal pad 19.

For example, a miniature coaxial radio frequency connector such as a Hirose U.FL type connector can be arranged as antenna connection means on a base substrate 5 or a second substrate 11.

Step E5A or E5B may be carried out after step E3 as described, but, alternatively, the connection means may also be arranged before sealing step E3. The method according to the present disclosure further comprises a step of electrically connecting the interdigital transducer with the antenna connection means, as illustrated, for example, by the electrical connection 17 in the first to fourth embodiments described above.

In a variant of the method according to the present disclosure, the base substrate 5 provided in step E1 may comprise a metallic layer 43 on its lower face 5b and at least one metal via 45a, 45b. In this way, an encapsulation system can be obtained according to the fourth embodiment illustrated in FIG. 4. In this variant, the via(s) 45a, 45b may be traversing or non-traversing, so as to be electrically insulated from the interdigital transducer 7. Furthermore, in this embodiment, the metallic layer 43 and the metal via 45a, 45b in the base substrate 5 provided may be of the same material. This makes it possible to increase the thermal conduction compatibility between metallic layer 43 and metal vias 45a, 45b, and to carry out combined production of metal vias 45a, 45b and the metallic layer 43 in one step.

In another embodiment of the method according to the present disclosure, the second substrate 11 sealed to the base substrate 5 in step E3 may comprise at least one via 23. Solder beads or bumps 27 are placed so as to obtain an electrical connection of the at least one transducer 7 with the antenna connection means using the at least one via 23. In this way, an encapsulation system can be obtained according to the second embodiment illustrated in FIG. 2. The method according to this variant has the advantage of particularly rapid manufacture: thus, by preparing the second substrate 11 with the electrical routing 25, the radio frequency connector 15 and the via or vias 23, and by placing the corresponding solder beads or bumps 27 on the SAW device 3, the encapsulation system 21 can be finalized in a single sealing step. It is preferable to place the beads or bumps during this sealing step ii to avoid melting or degradation of the solder beads or bumps during a subsequent sealing step. No assembly of parts or connections is necessary after sealing the base substrate 5 with the second substrate 11.

As described in the previous sections, the result is an encapsulation system that is more robust, compact and economical than previously known.

Of course, the present disclosure is not limited to the methods of use and examples described, and alternative embodiments may be used without departing from the scope of the invention as defined by the claims.

1. An encapsulation system for a surface acoustic wave (SAW) device, comprising:
the SAW device, the SAW device including a base substrate and at least one interdigital transducer on the base substrate;
a sealing joint sealing a second substrate with the base substrate so as to form a cavity enveloping the at least one interdigital transducer; and
an antenna connection means connected to the at least one interdigital transducer;
wherein the antenna connection means is disposed outside the cavity on the base substrate or on the second substrate.

2. The encapsulation system of claim 1, further comprising a wire bonding connecting the at least one interdigital transducer and the antenna connection means.

3. The encapsulation system of claim 1, further comprising at least one via traversing the second substrate and connecting the at least one interdigital transducer and the antenna connection means.

4. The encapsulation system of claim 3, further comprising one or more solder bumps in the cavity between the SAW device and the second substrate, the one or more solder bumps establishing an electrical connection with the at least one via traversing the second substrate.

5. The encapsulation system of claim 1, further comprising at least one metal pad on the base substrate, the at least one metal pad traversing the sealing joint and connecting the at least one interdigital transducer and the antenna connection means.

6. The encapsulation system of claim 1, further comprising a metallic layer on a face of the base substrate opposite the second substrate.

7. The encapsulation system of claim 1, wherein the base substrate comprises at least one metal via electrically insulated from the interdigital transducer.

8. The encapsulation system of claim 1, wherein the sealing joint is formed by anodic welding or by glass frit.

9. The encapsulation system of claim 8, wherein the sealing joint is formed by glass frit, the glass frit having a thermal expansion coefficient corresponding to that of a material of the base substrate and/or of the second substrate.

10. The encapsulation system of claim 1, wherein the second substrate comprises a same material as the base substrate.

11. A method for manufacturing a SAW device encapsulation system, the method comprising:
providing a base substrate including at least one interdigital transducer;
sealing a second substrate to the first substrate so as to form a cavity enveloping the at least one interdigital transducer; and
providing an antenna connection means outside of the cavity on the base substrate or the second substrate.

12. The method of claim 11, wherein the second substrate includes at least one via, the method further comprising electrically connecting the at least one interdigital transducer with the antenna connection means using the at least one via.

13. The method of claim 11, wherein the base substrate comprises a metallic layer on a face of the base substrate opposite the second substrate.

14. The method of claim 11, further comprising forming the antenna connection means to comprise a miniature coaxial radio frequency connector.

15. The encapsulation system of claim 1, wherein the sealing joint is formed by glass frit.

16. The encapsulation system of claim 1, wherein the antenna connection means comprise a miniature coaxial radio frequency connector.

17. The encapsulation system of claim 7, further comprising a metallic layer on a face of the base substrate opposite the second substrate, the metallic layer and the at least one metal via electrically insulated from the interdigital transducer comprising a same material.
